(19) United States
(12) Patent Application Publication
(10) Pub. No.: US 2015/0284849 A1
(43) Pub. Date: Oct. 8, 2015

(54) LOW-K FILMS WITH ENHANCED CROSSLINKING BY UV CURING

(71) Applicant: Applied Materials, Inc., Santa Clara, CA (US)

(72) Inventors: Kang Sub YIM, Palo Alto, CA (US); Taewan KIM, San Jose, CA (US); Alexandros T. DEMOS, Fremont, CA (US)

(73) Assignee: APPLIED MATERIALS, INC., Santa Clara, CA (US)

(21) Appl. No.: 14/657,627

(22) Filed: Mar. 13, 2015

Related U.S. Application Data
(60) Provisional application No. 61/976,446, filed on Apr. 7, 2014.

(51) Int. Cl. C23C 16/48; C23C 16/455; C23C 16/50; C23C 16/26

(52) U.S. Cl. CPC C23C 16/48; C23C 16/26; C23C 16/455; C23C 16/50

(57) ABSTRACT

Methods for making a low k porous dielectric film with improved mechanical strength are disclosed herein. A method of forming a dielectric layer can include delivering a deposition gas to a substrate in a processing chamber, the deposition gas comprising an acrylate precursor with a UV active side group and an oxygen containing precursor; activating the deposition gas to deposit an uncured carbon-containing layer on a surface of the substrate; and delivering UV radiation to the uncured carbon-containing layer to create a cured carbon-containing layer, the UV active side group crosslinking with a second group.

### CROSS-REFERENCE TO RELATED APPLICATIONS

This application claims priority to U.S. Provisional Patent Application Ser. No. 61/976,446, filed on Apr. 7, 2014, which is incorporated by reference herein.

### BACKGROUND

1. Field

Embodiments disclosed herein generally relate to methods of forming low dielectric constant layers. More specifically, embodiments generally relate to deposition of thin films using a precursor with a photoactive group.

2. Description of the Related Art

As the semiconductor industry introduces new generations of integrated circuits (IC's) having higher performance and greater functionality, the density of the elements that form those IC's is increased, while the dimensions, size and spacing between the individual components or elements are reduced. While in the past such reductions were limited only by the ability to define the structures photolithographically, device geometries having dimensions measured in um or nm have created new limiting factors, such as the conductivity of the metallic elements or the dielectric constant of the insulating material(s) used between the elements.

To achieve the low dielectric constant (low K) values which can be required by modern semiconductor devices, porous layers have been used to incorporate air (which has a K value of 1). Several methods have been pursued to induce porosity into low dielectric layers while maintaining structural integrity of the layer using materials such as organic, low-k polymers or organic polysilica, low-k polymers. One approach is to fabricate a hybrid organic-inorganic film using a mixture of silicon and organic precursors, with the film being subsequently cured using heat, electron beam (e-beam) or ultraviolet radiation (UV) to degrade the organic molecules. During UV curing, crosslinking reaction is accompanied with porogen removal, which enhances mechanical strength. However, the crosslinking mostly occurs with carbon removal, which is not desirable for film stability.

Therefore, there is a need for improved devices and methods for substrate process control.

### SUMMARY

Embodiments disclosed herein generally relate to methods of forming a low k layer. In one embodiment, a method for depositing a layer can include delivering a deposition gas having UV active side groups to a substrate in a processing chamber; activating the deposition gas to deposit an uncured carbon-containing layer having the UV active side groups on a surface of the substrate; and delivering UV radiation to the uncured carbon-containing layer to create a cured carbon-containing layer, the UV active side groups crosslinking with a second group. The deposition gas can include an acrylate precursor with a UV active side group and an oxygen containing precursor.

In another embodiment, a method for depositing a layer can include forming an uncured organosilicon layer having UV active side groups using a deposition gas; and delivering UV radiation to the uncured organosilicon layer to create a cured organosilicon layer, the UV active side group crosslinking with a second group, wherein the cured organosilicon layer has a hardness value of 1.5 gPa or greater. The deposition gas can include an organosilicon precursor with a UV active side group; and an oxygen containing precursor.

In another embodiment, a method for depositing a layer can include forming an uncured organosilicon layer using a deposition gas; delivering UV radiation to the uncured organosilicon layer to create a cured organosilicon layer, the UV active side group crosslinking with a second group, wherein the UV radiation has a wavelength between about 200 nm and about 600 nm, and wherein the cured organosilicon layer has a hardness value of 1.5 gPa or greater; and removing the saturated porogen either concurrent with or after forming the cured carbon-containing layer. The deposition gas can include an silylalkylacrylate precursor with a UV active side group; a saturated porogen; and oxygen containing precursor.

### BRIEF DESCRIPTION OF THE DRAWINGS

So that the manner in which the above recited features of the devices, systems and methods can be understood in detail, a more particular description of the devices, systems and methods, briefly summarized above, may be had by reference to embodiments, some of which are illustrated in the appended drawings. It is to be noted, however, that the appended drawings illustrate only typical embodiments and are therefore not to be considered limiting of its scope, for the disclosure may admit to other equally effective embodiments.

FIG. 1 is a schematic cross-sectional view of a CVD process chamber configured according to one or more embodiments; and

FIG. 2 is a flow diagram of a method for forming a porous organosilicon layer according to one or more embodiments.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

Embodiments disclosed herein generally relate to precursors for forming an ultra low k film having a dielectric constant less than about 2.5, such as about 2.2. More specifically, embodiments disclosed herein generally relate to precursors for generating an ultra low k film while maintaining mechanical strength of the deposited layer. The precursors described herein include a photoactive group, such as a UV active side group, which creates crosslinking without significant loss of carbon. By maintaining the carbon in the low k layer, the hardness of the layer can be maintained allowing for low k film that is stable below the 10 nm thickness boundary.

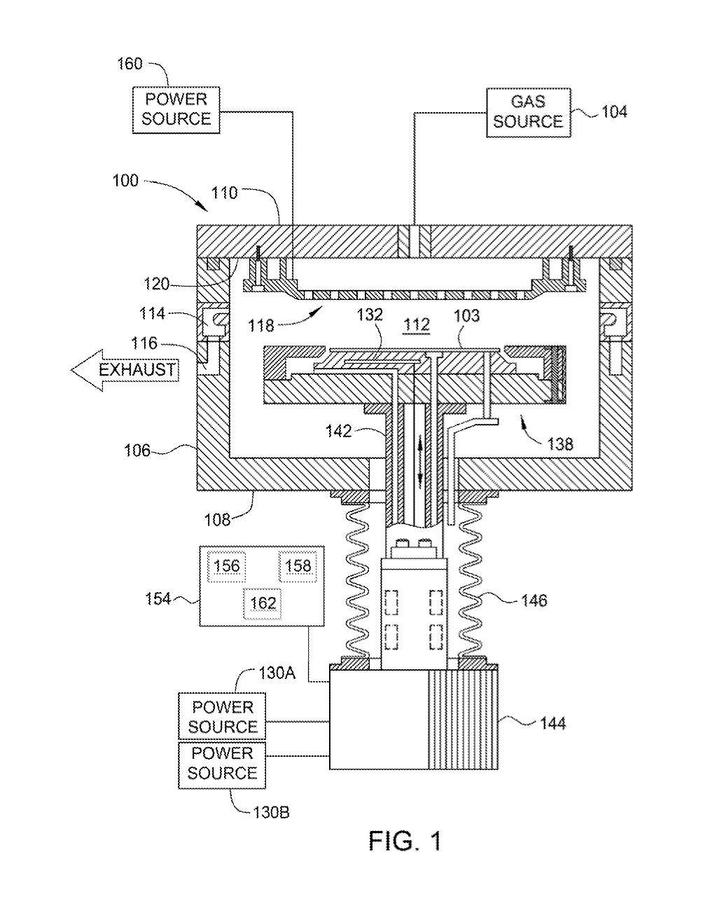

FIG. 1 is a schematic cross-sectional view of a CVD process chamber 100 that may be used for depositing a carbon based layer according to the embodiments described herein. A process chamber 100 is available from Applied Materials, Inc. located in Santa Clara, Calif., and a brief description thereof follows. Processing chambers that may be adapted to perform the carbon layer deposition methods described herein is the PRODUCER® chemical vapor deposition chamber, both available from Applied Materials, Inc. located in Santa Clara, Calif. It is to be understood that the chamber described below is an exemplary embodiment and other chambers, including chambers from other manufacturers, may be used with or modified to match embodiments described herein without diverging from the inventive characteristics described herein.

The process chamber 100 may be part of a processing system (not shown) that includes multiple processing chambers connected to a central transfer chamber (not shown) and serviced by a robot (not shown). The process chamber 100 includes walls 106, a bottom 108, and a lid 110 that define a process volume 112. The walls 106 and bottom 108 can be fabricated from a unitary block of aluminum. The process chamber 100 may also include a pumping ring 114 that fluidly couples the process volume 112 to an exhaust port 116 as well as other pumping components (not shown).

A substrate support assembly 138, which may be heated, may be centrally disposed within the process chamber 100. The substrate support assembly 138 supports a substrate 103 during a deposition process. The substrate support assembly 138 generally is fabricated from aluminum, ceramic or a combination of aluminum and ceramic, and includes at least one bias electrode 132.

A vacuum port may be used to apply a vacuum between the substrate 103 and the substrate support assembly 138 to secure the substrate 103 to the substrate support assembly 138 during the deposition process. The bias electrode 132, may be, for example, the electrode 132 disposed in the substrate support assembly 138, and coupled to a bias power source 130A and 130B, to bias the substrate support assembly 138 and substrate 103 positioned thereon to a predetermined bias power level while processing.

The bias power source 130A and 130B can be independently configured to deliver power to the substrate 103 and the substrate support assembly 138 at a variety of frequencies, such as a frequency between about 1 and about 60 MHz. In one embodiment, the bias power source 130A may be configured to deliver power to the substrate 103 at a frequency of about 2 MHz and the bias power source 130B may be configured to deliver power to the substrate 103 at a frequency of about 13.56 MHz. In another embodiment, the bias power source 130A may be configured to deliver power to the substrate 103 at a frequency of 2 MHz, the bias power source 130B may be configured to deliver power to the substrate 103 at a frequency of 13.56 MHz and a third power source (not shown) is configured to deliver power to the substrate 103 at a frequency of about 60 MHz. Various permutations of the frequencies described here can be employed without diverging from the embodiments described herein.

Generally, the substrate support assembly 138 is coupled to a stem 142. The stem 142 provides a conduit for electrical leads, vacuum and gas supply lines between the substrate support assembly 138 and other components of the process chamber 100. Additionally, the stem 142 couples the substrate support assembly 138 to a lift system 144 that moves the substrate support assembly 138 between an elevated position (as shown in FIG. 1) and a lowered position (not shown) to facilitate robotic transfer. Bellows 146 provide a vacuum seal between the process volume 112 and the atmosphere outside the chamber 100 while facilitating the movement of the substrate support assembly 138.

The showerhead 118 may generally be coupled to an interior side 120 of the lid 110. Gases (i.e., process and other gases) that enter the process chamber 100 pass through the showerhead 118 and into the process chamber 100. The showerhead 118 may be configured to provide a uniform flow of gases to the process chamber 100. Uniform gas flow is desirable to promote uniform layer formation on the substrate 103. A plasma power source 160 may be coupled to the showerhead 118 to energize the gases through the showerhead 118 towards substrate 103 disposed on the substrate support assembly 138. The plasma power source 160 may provide RF power. Further, the plasma power source 160 can be configured to deliver power to the showerhead 118 at a at a variety of frequencies, such as a frequency between about 100 MHz and about 200 MHz. In one embodiment, the plasma power source 160 is configured to deliver power to the showerhead 118 at a frequency of 162 MHz.

The function of the process chamber 100 can be controlled by a computing device 154. The computing device 154 may be one of any form of general purpose computer that can be used in an industrial setting for controlling various chambers and sub-processors. The computing device 154 includes a computer processor 156. The computing device 154 includes memory 158. The memory 158 may include any suitable memory, such as random access memory, read only memory, flash memory, hard disk, or any other form of digital storage, local or remote. The computing device 154 may include various support circuits 162, which may be coupled to the computer processor 156 for supporting the computer processor 156 in a conventional manner. Software routines, as required, may be stored in the memory 156 or executed by a second computing device (not shown) that is remotely located.

The computing device 154 may further include one or more computer readable media (not shown). Computer readable media generally includes any device, located either locally or remotely, which is capable of storing information that is retrievable by a computing device. Examples of computer readable media 154 useable with embodiments of the present embodiments include solid state memory, floppy disks, internal or external hard drives, and optical memory (CDs, DVDs, BR-D, etc). In one embodiment, the memory 158 may be the computer readable media. Software routines may be stored on the computer readable media to be executed by the computing device.

The software routines, when executed, transform the general purpose computer into a specific process computer that controls the chamber operation so that a chamber process is performed. Alternatively, the software routines may be performed in hardware as an application specific integrated circuit or other type of hardware implementation, or a combination of software and hardware.

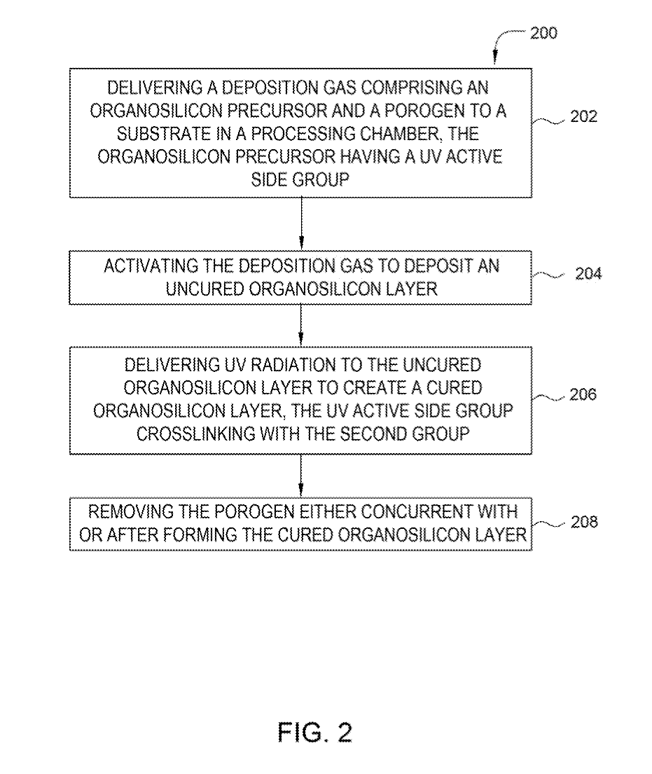

FIG. 2 is a flow diagram of a method 200 for depositing a dielectric layer according to one embodiment. By delivering a precursor with UV active side groups and activating the precursor at a specific UV range, a high hardness low k carbon layer can be formed on the surface of the substrate. The hardness can be greater than or equal to about 1.5 gPa. The k value can be less than or equal to about 2.5, such as less than 2.2. The method 200 begins at 202 by delivering a deposition gas comprising an organosilicon precursor and a porogen to a substrate in a processing chamber. The substrate can be of any composition, such as a crystalline silicon substrate. The substrate can also include one or more features, such as a via or an interconnect.

The processing chamber used with one or more embodiments can be any CVD processing chamber, such as the processing chamber 100 described above or chambers from other manufacturers. Flow rates and other processing parameters described below are for a 300 mm substrate. It should be understood these parameters can be adjusted based on the size of the substrate processed and the type of chamber used without diverging from the embodiments disclosed herein.

A “substrate surface”, as used herein, refers to any substrate or material surface formed on a substrate upon which film processing is performed. For example, a substrate surface on which processing can be performed includes materials such as silicon, silicon oxide, silicon nitride, doped silicon, germanium, gallium arsenide, glass, sapphire, and any other materials such as metals, metal nitrides, metal alloys, and other conductive materials, depending on the application. A substrate surface may also include dielectric materials such as silicon dioxide and carbon doped silicon oxides. Substrates may have various dimensions, such as 200 mm, 300 mm or other diameter wafers, as well as rectangular or square panes.

In at least one embodiment, the deposition gas is introduced into the interior volume 112 through the showerhead 118. The deposition gas can be delivered with a carrier gas, such as argon. The deposition gas may be introduced into the processing chamber at a flow rate of between about 20 sccm and about 2000 sccm for a 300 mm substrate. The deposition gas and the carrier gas can be introduced into the chamber separately or after combining or premixing the deposition gas and the carrier gas. The chamber pressure during processing can be maintained between about 10 mTorr and about 500 mTorr for a 300 mm substrate. 500 degrees Celsius during the deposition process. In one embodiment, the chamber can heat the substrate to about 25 degrees Celsius. In another embodiment, the chamber can heat the substrate to a temperature between 5 degrees Celsius and 100 degrees Celsius.

The organosilicon precursor has a UV active side group. The organosilicon precursors can include Hexanedioldiacrylate, Tripropyleneglycoldiacrylate, Aliphatic Urethane Acrylate, Glycerinetriacrylate, Bisphenol A Epoxydiacrylate, Aromatic Urethane Acrylate. In one embodiment, the organosilicon precursor Is a silylalkylacrylate. The UV active side group is generally defined as a chain of at least 2 carbon atoms which includes one or more double bonds and one or more oxygen atoms, such as aryl ketone, acrylates and others. The table below shows some further examples of organosilicon precursors with UV active side groups.

TABLE 1

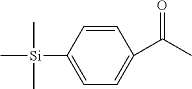

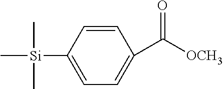

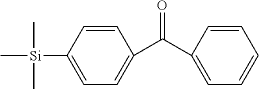 [SMILES: C[Si](C)(C)c1ccc(C(=O)c2ccccc2)cc1]

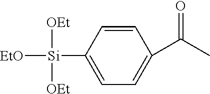 [SMILES: CCO[Si](OCC)(OCC)c1ccc(C(C)=O)cc1]

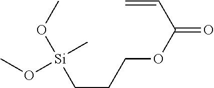

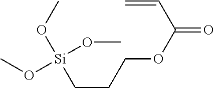

| | |
|---|---|
| 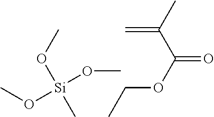 | 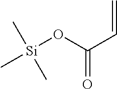 |

| | |
|---|---|
| 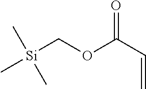 | 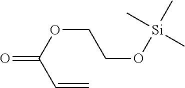 |

The deposition gas can further include an oxygen-containing precursor and a porogen. Oxygen-containing precursors can include O₂, O₃, H₂O, N₂O combinations thereof or various oxidizing gases. In one embodiment, the oxygen-containing gas is O₂. Porogens can include a member selected from the group consisting of cyclooctene, cycloheptene, cyclooctane, cycloheptane, cyclohexene, cyclohexane, and bicyclic chemicals and mixtures thereof. In one embodiment, the porogen is a saturated porogen.

The deposition gas is then activated to deposit an uncured organosilicon layer, at 204. The deposition gas can be delivered to the chamber in the presence of a source plasma power. The source plasma power can be delivered by a power source, such as the plasma power source 160 described with reference to FIG. 1. The source plasma power applied to the chamber to generate and maintain a plasma of the deposition gas, which can include both the organosilicon precursor, the oxygen-containing precursor and the carrier gas, can be an RF power. The source plasma power can be delivered at a frequency of from about 2 MHz to about 170 MHz and at a power level of between 100 W and 2000 W, for a 300 mm substrate (between 0.11 W/cm² of the top surface of the substrate and 2.22 W/cm² of the top surface of the substrate). Other embodiments include delivering the source plasma power at from about 500 W to about 1500 W, for a 300 mm substrate (from 0.11 W/cm² of the top surface of the substrate to 2.22 W/cm² of the top surface of the substrate). The power applied can be adjusted according to size of the substrate being processed.

The UV radiation can then be delivered to the uncured organosilicon layer to create a cured organosilicon layer, at 206. The carbon double bond of the UV active side group is activated by UV radiation. This UV active group can absorb UV energy at specific wavelength range to provide the activation energy for the crosslinking reaction. The UV radiation may be a broad spectrum radiation, such as UV radiation between about 200 nm and 600 nm. In one embodiment, the UV radiation is produced by a mercury type UV lamp. As described, one or more carbon groups from the UV active side group are involved in the crosslinking, which reduces possible carbon loss from the organosilicon layer. The UV radiation can be delivered at a power of between 5% of maximum power and 95% of maximum power.

By exposing the uncured organosilicon layer to the UV radiation, the UV active side group is activated and crosslinks with a second group. The second group can be a portion of a molecule which bonds with the UV active group in the presence of UV. The second group can be another UV active group, an acrylate group, a methyl group, a silicon atom, an exposed oxygen or another crosslinking site. The molecule with the second group can be a variety of organosilicon compounds, either with or without a UV active side group, including octamethylcyclotetrasiloxane (OMCTS) or diethoxy methylsilane (DEMS). The UV active side group and the second group can both be portions of the same molecule, such as a the UV active side group of a first silylalkylacrylate molecule crosslinking to a second group of a second silylalkylacrylate molecule. In another embodiment, the UV active side group is part of a first type or class of molecule and the second group is part of a second type or class of molecule, such as a UV active side group of a silylalkylacrylate molecule interacting with the second group of a octamethylcyclotetrasiloxane (OMCTS) or diethoxy methylsilane (DEMS) molecule.

Then, the porogen can be removed either concurrently with or after forming the cured carbon layer, at 208. The porogen described above can be removed concurrently with the cure step for the organosilicon layer. In one embodiment, the porogen is removed during the curing process by using a porogen which is activated by the same UV radiation as described above. Further, the porogen can be removed after the organosilicon layer is cured. In another embodiment, the porogen can be removed by a pore-forming plasma. The pore-forming plasma can include an oxidizing gas or a reducing gas. The pore-forming plasma activates or reacts with the porogen to abstract at least a portion of the porogen from the organosilicon layer, leaving behind a plurality of pores.

The embodiments described herein generally relate to the formation of a porous mechanically strong dielectric layer. The loss of carbon during the curing process is believed to create hardness deficiencies in the low k layers. Through the use of organosilicon precursors with a UV active side group, such as acrylates, less carbon is lost during the curing process. By maintaining the carbon quantity, the thinner, harder films can be deposited.

While the foregoing is directed to embodiments of the present disclosure, other and further embodiments may be devised without departing from the basic scope thereof, and the scope thereof is determined by the claims that follow.

1. A method for depositing a layer, comprising:
delivering a deposition gas to a substrate in a processing chamber, the deposition gas comprising:
an acrylate precursor with a UV active side group; and
an oxygen containing precursor;
activating the deposition gas to deposit an uncured carbon-containing layer on a surface of the substrate; and
delivering UV radiation to the uncured carbon-containing layer to create a cured carbon-containing layer, the UV active side group crosslinking with a second group.

2. The method of claim 1, wherein the acrylate precursor is a silylalkylacrylate.

3. The method of claim 1, wherein the deposition gas comprises a porogen.

4. The method of claim 3, wherein the porogen is a saturated porogen.

5. The method of claim 3, further comprising removing the porogen either concurrent with or after forming the cured carbon-containing layer.

6. The method of claim 1, wherein the oxygen containing precursor comprises O₂, O₃, H₂O or combinations thereof.

7. The method of claim 1, wherein the UV radiation has a wavelength between about 200 nm and about 600 nm.

8. The method of claim 1, wherein the second group has an oxygen which forms the bond to the UV active side group.

9. The method of claim 1, wherein the second group comprises a methyl group which forms the bond to the UV active side group.

10. A method for depositing a layer, comprising:
forming an uncured organosilicon layer using a deposition gas comprising:
an organosilicon precursor with a UV active side group; and
an oxygen containing precursor; and
delivering UV radiation to the uncured organosilicon layer to create a cured organosilicon layer, the UV active side group crosslinking with a second group, wherein the cured organosilicon layer has a hardness value of 1.5 gPa or greater.

11. The method of claim 10, wherein the organosilicon precursor comprises an acrylate precursor.

12. The method of claim 10, wherein the organosilicon precursor comprises a silylalkylacrylate.

13. The method of claim 10, wherein the deposition gas comprises a porogen.

14. The method of claim 13, wherein the porogen is a saturated porogen.

15. The method of claim 10, wherein the UV radiation has a wavelength between about 200 nm and about 600 nm.

16. The method of claim 10, wherein the oxygen containing precursor comprises O₂, O₃, H₂O or combinations thereof.

17. The method of claim 10, wherein the second group has an oxygen which forms the bond to the UV active side group.

18. The method of claim 10, wherein the second group has a methyl group which forms the bond to the UV active side group.

19. A method for depositing a layer, comprising:
forming an uncured organosilicon layer using a deposition gas comprising:
an silylalkylacrylate precursor with a UV active side group;
a saturated porogen; and
an oxygen containing precursor; and
delivering UV radiation to the uncured organosilicon layer to create a cured organosilicon layer, the UV active side group crosslinking with a second group, wherein the UV radiation has a wavelength between about 200 nm and about 600 nm, and wherein the cured organosilicon layer has a hardness value of 1.5 gPa or greater; and
removing the saturated porogen either concurrent with or after forming the cured carbon-containing layer.

20. The method of claim 19, wherein the second group has an oxygen or a methyl group which forms the bond to the UV active side group.
